(19) United States
(12) Patent Application Publication
(10) Pub. No.: US 2018/0331044 A1
(43) Pub. Date: Nov. 15, 2018

(54) SEMICONDUCTOR DEVICE AND FABRICATION METHOD THEREOF

(71) Applicant: United Microelectronics Corp., Hsinchu (TW)

(72) Inventors: Yi-Yu Wu, Chiayi County (TW); Chun-Yuan Wu, Yunlin County (TW); Chih-Chien Liu, Taipei City (TW); Bin-Siang Tsai, Changhua County (TW)

(73) Assignee: United Microelectronics Corp., Hsinchu (TW)

(21) Appl. No.: 15/624,498

(22) Filed: Jun. 15, 2017

(30) Foreign Application Priority Data
May 12, 2017 (TW) 106115874

(51) Int. Cl. H01L 23/532; H01L 23/528; H01L 23/522; H01L 21/02; H01L 21/768

(52) U.S. Cl. CPC H01L 23/53257; H01L 23/528; H01L 23/5226; H01L 23/53295; H01L 21/02244; H01L 23/53228; H01L 21/02175; H01L 21/02164; H01L 21/76877; H01L 21/02252; H01L 21/02068

(57) ABSTRACT

A semiconductor device including a tungsten contact structure formed in a first dielectric layer on a substrate is provided. The tungsten contact structure contains a seam structure. A tungsten oxide layer is formed at least on a sidewall of the seam structure.

### CROSS REFERENCE TO RELATED APPLICATION

This application claims the priority benefits of Taiwan application serial no. 106115874, filed on May 12, 2017. The entirety of the above-mentioned patent application is hereby incorporated by reference herein and made a part of specification.

### BACKGROUND OF THE INVENTION

### Field of the Invention

The invention relates to a semiconductor fabrication technique, and in particular, fabrication of a tungsten contact structure.

### Description of Related Art

In an overall structure of a semiconductor device, to accomplish a designed connection structure of an integrated circuit, the semiconductor device generally includes a contact structure to connect circuit components of different heights. The contact structure generally uses tungsten metal as its material.

The tungsten contact structure is generally formed in a dielectric layer to achieve electrical connection between circuit components in upper and lower layers of the dielectric layer. In a fabrication process of the tungsten contact structure, an opening is first formed in the dielectric layer, and a tungsten material is filled in the opening to complete the tungsten contact structure and further achieve the effect of electrical connection between upper and lower circuit components in the dielectric layer.

The quality of the tungsten contact structure has an impact on the electrical connection between the upper and lower circuit components in the dielectric layer. Therefore, in the fabrication process, damages to the tungsten contact structure should be avoided.

### SUMMARY OF THE INVENTION

According to an embodiment of the invention, the invention provides a semiconductor device including a tungsten contact structure formed in a first dielectric layer on a substrate. A seam structure exists in the tungsten contact structure. A tungsten oxide layer is formed at least on a sidewall of the seam structure.

According to an embodiment of the invention, in the semiconductor device, a thickness of the tungsten oxide layer is in a range of 25 A (angstrom) to 35 A.

According to an embodiment of the invention, in the semiconductor device, a thickness of the tungsten oxide layer is in a range of 27 A to 32 A.

According to an embodiment of the invention, in the semiconductor device, the tungsten oxide layer is also forming on an upper surface of the tungsten contact structure, before the tungsten contact structure is wet cleaned.

According to an embodiment of the invention, in the semiconductor device, the first dielectric layer is a silicon oxide layer.

According to an embodiment of the invention, the semiconductor device further includes a second dielectric layer covering the tungsten contact structure and the first dielectric layer. A plug structure is formed in the second dielectric layer on the tungsten contact structure and is in electrical contact with the tungsten contact structure.

According to an embodiment of the invention, in the semiconductor device, the first dielectric layer is a multi-layer stack structure.

According to an embodiment of the invention, in the semiconductor device, the substrate includes a wafer and a component structure completed on the wafer.

According to an embodiment of the invention, the invention provides a semiconductor device fabrication method including: forming a first dielectric layer on a substrate; forming a tungsten contact structure in the first dielectric layer; performing a plasma treatment of an oxygen-containing gas on the tungsten contact structure to form a tungsten oxide layer on an exposed surface of the tungsten contact structure; and performing a wet cleaning on the tungsten contact structure.

According to an embodiment of the invention, in the semiconductor device fabrication method, a thickness of the tungsten oxide layer is in a range of 25 A to 35 A.

According to an embodiment of the invention, in the semiconductor device fabrication method, a thickness of the tungsten oxide layer is in a range of 27 A to 32 A.

According to an embodiment of the invention, in the semiconductor device fabrication method, a seam structure exists in the tungsten contact structure.

According to an embodiment of the invention, in the semiconductor device fabrication method, the tungsten oxide layer is alined on an upper surface of the tungsten contact structure and on a sidewall of the seam structure, before the wet cleaning is performed.

According to an embodiment of the invention, in the semiconductor device fabrication method, the first dielectric layer is a silicon oxide layer.

According to an embodiment of the invention, the semiconductor device fabrication method further includes forming a second dielectric layer on the tungsten contact structure and the first dielectric layer; and forming a plug structure in the second dielectric layer on the tungsten contact structure, the plug structure being in electrical contact with the tungsten contact structure.

According to an embodiment of the invention, in the semiconductor device fabrication method, the first dielectric layer is a multi-layer stack structure.

According to an embodiment of the invention, in the semiconductor device fabrication method, the substrate includes a wafer and a component structure completed on the wafer.

In the tungsten contact structure of the invention, before the wet cleaning is performed, the plasma treatment of an oxygen-containing gas is first performed on the tungsten contact structure. In addition to forming tungsten oxide on the surface of the tungsten contact structure, tungsten oxide is also formed on the sidewall surface of the seam structure. Accordingly, damage to the tungsten material due to erosion by H₂O₂ is effectively prevented, and the seam structure is effectively prevented from being widened through the protection of tungsten oxide.

To provide a further understanding of the aforementioned and other features and advantages of the invention, exemplary embodiments, together with the reference drawings, are described in detail below.

### BRIEF DESCRIPTION OF THE DRAWINGS

FIG. 1 is a cross-sectional schematic diagram illustrating a tungsten contact structure according to an embodiment of the invention.

FIG. 2 is a cross-sectional schematic diagram illustrating a tungsten contact structure containing a seam structure according to an embodiment of the invention.

FIG. 3 is a cross-sectional schematic diagram illustrating a tungsten contact structure containing a seam structure after a plasma treatment of an oxygen-containing gas according to an embodiment of the invention.

FIG. 4 is a cross-sectional schematic diagram illustrating a semiconductor device including a tungsten contact structure according to an embodiment of the invention.

FIG. 5 is a cross-sectional schematic diagram illustrating a semiconductor device including a tungsten contact structure according to an embodiment of the invention.

FIG. 6 is a flowchart illustrating steps of a semiconductor device fabrication method according to an embodiment of the invention.

### DESCRIPTION OF THE EMBODIMENTS

The invention relates to fabrication of a tungsten contact structure in semiconductor manufacturing technology.

In a forming process, a tungsten contact structure is formed starting from a sidewall of an opening of a dielectric layer. Therefore, a seam structure inevitably exists in some tungsten contact structures. After the tungsten contact structure is completed, a wet cleaning process is performed thereon. In the wet cleaning process, a cleaning solution containing hydrogen peroxide (H₂O₂) is generally used. The H₂O₂ cleaning solution erodes tungsten materials. If a seam structure exists in the tungsten contact structure, the seam structure is eroded by H₂O₂ and is widened, resulting in a noticeable recess on an upper surface of the tungsten contact structure. The recess will have an impact on the effect of subsequent electrical connection.

The invention effectively reduces widening of the recess, so that more desirable electrical connection effect of a subsequently fainted component can be maintained.

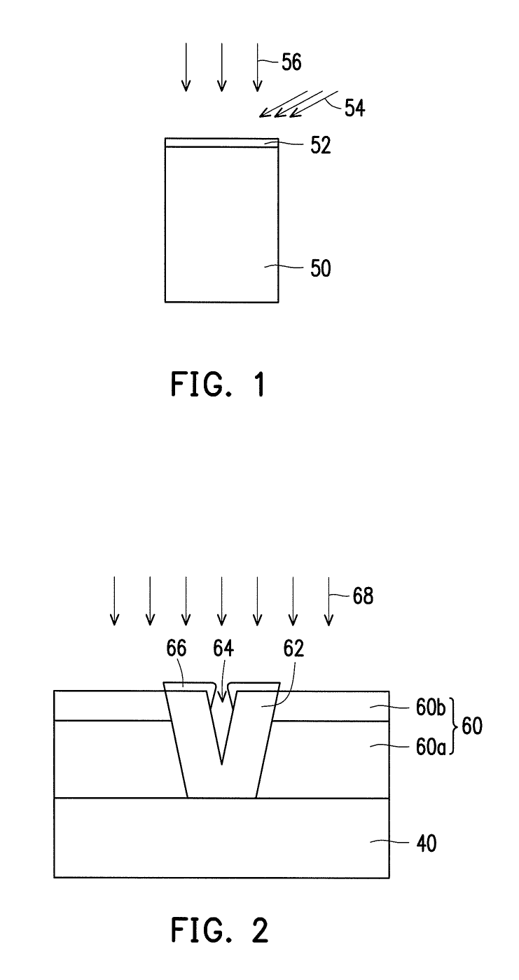

FIG. 1 is a cross-sectional schematic diagram illustrating a tungsten contact structure according to an embodiment of the invention. Referring to FIG. 1, in the invention, a tungsten oxide layer 52 is formed on an upper surface of a tungsten contact structure 50. A thickness of the tungsten oxide layer 52 in an embodiment is, for example, in a range of 25 A (angstrom) to 35 A or in a range of 27 A to 32 A, but is not limited hereto. A formation method of the tungsten oxide layer 52 in an embodiment involves, for example, applying a plasma treatment 56 of an oxygen-containing gas to a tungsten surface to form the tungsten oxide layer 52 on a surface of the tungsten contact structure 50. Then, the tungsten contact structure 50 including the tungsten oxide layer 52 is prevented from being eroded by H₂O₂ in a cleaning solution in a subsequent process of a wet cleaning 54.

By applying the plasma treatment 56 of an oxygen-containing gas to the tungsten contact structure 50, the protection effect on the tungsten contact structure 50 in which a seam structure exists is more significant. The following is a description of an embodiment where the tungsten contact structure 50 contains a seam structure.

FIG. 2 is a cross-sectional schematic diagram illustrating a tungsten contact structure containing a seam structure according to an embodiment of the invention. Referring to FIG. 2, a tungsten contact structure 62 is formed in a dielectric layer 60 on a substrate 40. In the present embodiment, the description is based on an example where the tungsten contact structure 62 contains a seam structure 64. The substrate 40, for example, includes a wafer and a component structure completed on the wafer. The component structure needs to be upwardly electrically connected to other circuit components through the tungsten contact structure 62, wherein a height is provided by the dielectric layer 60. Therefore, the tungsten contact structure 62 is formed in the dielectric layer 60. In an embodiment, the dielectric layer 60 is a mono-layer or multi-layer stack structure. The multi-layer stack structure is, for example, formed by stacking a plurality of dielectric layers 60a, 60b but is not limited hereto. The seam structure 64 is, for example, V-shaped (with a narrow bottom and a wide top), spindle-shaped (with a wide middle and narrow bottom and top), rectangular, etc., but is not limited hereto.

An upper surface of the tungsten contact structure 62 is in an exposed state. Next, a plasma treatment 68 of an oxygen-containing gas is performed on the upper surface of the tungsten contact structure 62. After the plasma treatment 68, a tungsten oxide layer 66 is formed on the upper surface of the tungsten contact structure 62. Here, the oxygen-containing gas is, for example, O₂, O₃, or N₂O but is not limited hereto.

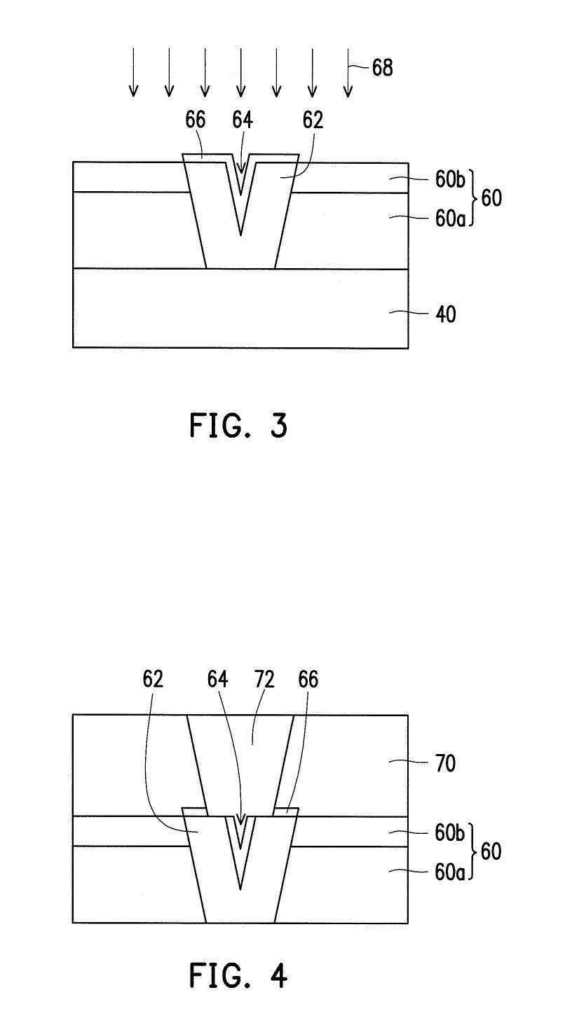

FIG. 3 is a cross-sectional schematic diagram illustrating a tungsten contact structure containing a seam structure after a plasma treatment of an oxygen-containing gas according to an embodiment of the invention. Referring to FIG. 3, the invention adopts the plasma treatment 68 of an oxygen-containing gas. Due to excellent flowability of gas, if the seam structure 64 exists in the tungsten contact structure 62, the tungsten oxide layer 66 is also formed on a sidewall of the seam structure 64. In other words, the tungsten oxide layer 66 also effectively covers a surface of the seam structure 64.

Since the tungsten oxide layer 66 also effectively covers the surface of the seam structure 64, in a subsequent process of a wet cleaning, the tungsten oxide layer 66 resists erosion by H₂O₂ in the cleaning solution. Accordingly, the tungsten oxide layer 66 can further effectively prevent the seam structure 64 from being widened by the erosion of H₂O₂ and thereby avoid causing a recess on the surface of the tungsten contact structure 62.

The invention has been verified with actual samples. After the plasma treatment 68 of an oxygen-containing gas was applied to the tungsten contact structure 62, recesses on the surface of the tungsten contact structure 62 were indeed reduced.

In subsequent processes of the semiconductor device, other circuit components are then formed according to the design of the circuit and are electrically connected to the circuit component on the substrate 40 through the tungsten contact structure 62.

FIG. 4 is a cross-sectional schematic diagram illustrating a semiconductor device including a tungsten contact structure according to an embodiment of the invention. Referring to FIG. 4, in an embodiment, after the tungsten contact structure 62 is fabricated, a contact plug 72, for example, is subsequently formed to connect an upper-layer component. A material of the plug 72 is, for example, copper. The plug 72 is formed, for example, in another dielectric layer 70, which, for example, is a silicon oxide layer. Moreover, if it is necessary to accommodate fabrication of components at other parts, the dielectric layer 70 may be a stack of stacked layers, for example, similar to the dielectric layer 60. In the dielectric layer 70, an opening is similarly formed first to expose the tungsten contact structure 62, wherein part of the tungsten oxide layer 66 is also removed. Then, a copper material is filled in the opening to complete the plug 72. The plug 72 is in electrical contact with the tungsten contact structure 62 to form a path of electrical connection.

In the process of forming the opening, a patterned photoresist layer (not illustrated) is first formed on the dielectric layer 70 to define a location of the opening. Then, the opening is etched in the dielectric layer 70 through a dry etching process until the tungsten contact structure 62 is exposed. Next, polymers, residues, by-products, etc. in the etching process are removed through a wet cleaning. At this time, if H₂O₂ in the wet cleaning solution directly contacts the exposed tungsten contact structure 62, it is likely to erode the tungsten contact structure 62 or even further erode and widen the seam structure 64. In the invention, since the tungsten oxide layer 66 also effectively covers the surface of the seam structure 64, in the process of the wet cleaning, the tungsten oxide layer 66 resists erosion by H₂O₂ in the cleaning solution. Therefore, the tungsten oxide layer 66 can further effectively prevent the seam structure 64 from being widened by the erosion of H₂O₂.

The foregoing embodiment of FIG. 4 has described the example where the opening of the dielectric layer 70 is smaller than the tungsten contact structure 62. Before the copper material is filled in the opening, a cleaning process (dry etching cleaning) is additionally performed to remove the tungsten oxide layer 66 on a portion of the surface exposed by the opening to reduce a contact resistance between the tungsten contact structure 62 and the plug 72. Due to a small contact area with an etchant, the tungsten oxide layer 66 in the seam structure 64 is likely to partially remain, as shown in FIG. 4. In other embodiments, if the opening of the dielectric layer 70 is larger than the tungsten contact structure 62, the tungsten oxide layer 66 on the surface will be entirely removed, but the tungsten oxide layer 66 in the seam structure 64 is still likely to partially remain.

The foregoing embodiment of FIG. 4 describes the case where the seam structure 64 exists in the tungsten contact structure 62. In fabrication, there is a great possibility that the seam structure 64 will occur. However, in some tungsten contact structures 62, the seam structure 64 may be small and not obvious or may be fully filled (i.e., the seam structure 64 does not exist).

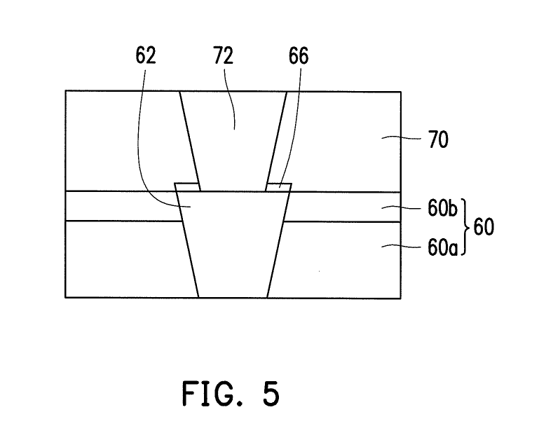

FIG. 5 is a cross-sectional schematic diagram illustrating a semiconductor device including a tungsten contact structure according to an embodiment of the invention. Referring to FIG. 5, in the case where the tungsten contact structure 62 does not contain the seam structure 64, the plug 72 and the tungsten contact structure 62 are in direct contact without containing the seam structure 64. However, in terms of the fabrication method, the plasma treatment 68 of an oxygen-containing gas does not require a distinction whether the tungsten contact structure 62 contains the seam structure 64.

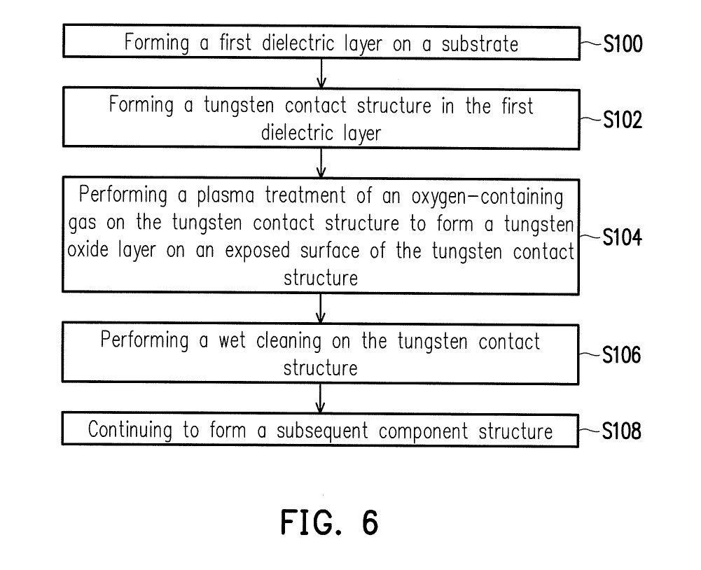

FIG. 6 is a flowchart illustrating steps of a semiconductor device fabrication method according to an embodiment of the invention. Referring to FIG. 6, another embodiment relating to a semiconductor device fabrication method is provided. The semiconductor device fabrication method includes forming a first dielectric layer on a substrate in step S100. In step S102, a tungsten contact structure is formed in the first dielectric layer. In step S104, a plasma treatment of an oxygen-containing gas is performed on the tungsten contact structure to form a tungsten oxide layer on an exposed surface of the tungsten contact structure. In step S106, a wet cleaning is performed on the tungsten contact structure. In step S108, a subsequent component structure is then formed. Accordingly, it is not necessary to distinguish whether the tungsten contact structure 62 contains the seam structure 64 in the plasma treatment of an oxygen-containing gas in step S104. If the tungsten contact structure 62 contains the seam structure 64, the seam structure 64 is protected and is not substantially widened.

In the invention, in the process of forming the tungsten contact structure 62, before the wet cleaning is performed, the plasma treatment of an oxygen-containing gas is first performed on the tungsten contact structure 62. Accordingly, when the seam structure 64 exists, the seam structure 64 is effectively prevented from being widened by the erosion of H₂O₂, which causes a recess on the surface.

Although the invention is disclosed as the embodiments above, the embodiments are not meant to limit the invention. Any person skilled in the art may make slight modifications and variations without departing from the spirit and scope of the invention. Therefore, the protection scope of the invention shall be defined by the claims attached below.

1. A semiconductor device comprising:
a tungsten contact structure formed in a first dielectric layer on a substrate, wherein a seam structure exists in the tungsten contact structure; and
a tungsten oxide layer formed at least on a sidewall of the seam structure.

2. The semiconductor device according to claim 1, wherein a thickness of the tungsten oxide layer is in a range of 25 A to 35 A.

3. The semiconductor device according to claim 1, wherein a thickness of the tungsten oxide layer is in a range of 27 A to 32 A.

4. The semiconductor device according to claim 1, wherein the tungsten oxide layer is also formed on an upper surface of the tungsten contact structure.

5. The semiconductor device according to claim 1, wherein the first dielectric layer is a silicon oxide layer.

6. The semiconductor device according to claim 1, further comprising:
a second dielectric layer covering the tungsten contact structure and the first dielectric layer; and
a plug structure formed in the second dielectric layer on the tungsten contact structure, the plug structure being in electrical contact with the tungsten contact structure.

7. The semiconductor device according to claim 6, wherein the first dielectric layer is a multi-layer stack structure.

8. The semiconductor device according to claim 1, wherein the substrate comprises a wafer and a component structure completed on the wafer.

9. A semiconductor device fabrication method comprising:
forming a first dielectric layer on a substrate;
forming a tungsten contact structure in the first dielectric layer;
performing a plasma treatment of an oxygen-containing gas on the tungsten contact structure to form a tungsten oxide layer on an exposed surface of the tungsten contact structure; and
performing a wet cleaning on the tungsten contact structure.

10. The semiconductor device fabrication method according to claim 9, wherein a thickness of the tungsten oxide layer is in a range of 25 A to 35 A.

11. The semiconductor device fabrication method according to claim 9, wherein a thickness of the tungsten oxide layer is in a range of 27 A to 32 A.

12. The semiconductor device fabrication method according to claim 9, wherein a seam structure exists in the tungsten contact structure.

13. The semiconductor device fabrication method according to claim 12, wherein the tungsten oxide layer is formed on an upper surface of the tungsten contact structure and on a sidewall of the seam structure, before the wet cleaning is performed.

14. The semiconductor device fabrication method according to claim 9, wherein the first dielectric layer is a silicon oxide layer.

15. The semiconductor device fabrication method according to claim 9, further comprising:
forming a second dielectric layer on the tungsten contact structure and the first dielectric layer; and
forming a plug structure in the second dielectric layer on the tungsten contact structure, the plug structure being in electrical contact with the tungsten contact structure.

16. The semiconductor device fabrication method according to claim 15, wherein the first dielectric layer is a multi-layer stack structure.

17. The semiconductor device fabrication method according to claim 9, wherein the substrate comprises a wafer and a component structure completed on the wafer.

18. The semiconductor device according to claim 1, wherein the tungsten oxide layer fully covers the sidewall of the seam structure.

19. The semiconductor device according to claim 1, wherein the tungsten oxide layer at least covers a bottom of the sidewall of the seam structure.

20. The semiconductor device according to claim 1, wherein the seam structure with the tungsten oxide layer remains as an opening structure.
